(19) United States
(12) Patent Application Publication
(10) Pub. No.: US 2025/0360697 A1
(43) Pub. Date: Nov. 27, 2025

(54) POROUS RESIN SHEET AND CARRIER TAPE

(71) Applicant: YUPO CORPORATION, Tokyo (JP)

(72) Inventor: Yosuke HIROI, Ibaraki (JP)

(73) Assignee: YUPO CORPORATION, Tokyo (JP)

(21) Appl. No.: 18/875,957

(22) PCT Filed: Jun. 20, 2023
(86) PCT No.: PCT/JP2023/022822

§ 371 Date: Dec. 17, 2024

(30) Foreign Application Priority Data
Jun. 24, 2022 (JP) 2022-102194

(51) Int. Cl. B32B 27/08; B32B 27/32

(52) U.S. Cl. CPC B32B 27/08; B32B 27/32; B32B 2250/03; B32B 2307/516; B32B 2307/518; B32B 2307/546; B32B 2307/7376

(57) ABSTRACT

A porous resin sheet includes a porous resin layer containing a thermoplastic resin. The porous resin layer has a thickness of 40 to 350 μm. The porous resin layer has a porosity of 35 to 80%. The porous resin layer includes a substrate layer and a first surface layer, and each of the substrate layer and the first surface layer contains a thermoplastic resin and particles. A content of the particles in the substrate layer is 20 to 45 mass %, and a content of the particles in the first surface layer is 45 to 80 mass %

### TECHNICAL FIELD

The present invention relates to a porous resin sheet and a carrier tape.

### BACKGROUND ART

A carrier tape is used to facilitate handling, such as transport, of electronic parts that have become smaller and smaller. Such a carrier tape has pockets for individually accommodating electronic parts, which makes it easy to prevent the electronic parts from being lost or damaged.

Generally, a carrier tape is made of pulp paper or a resin such as polyvinyl chloride, polystyrene, amorphous polyethylene terephthalate, polycarbonate, or polypropylene. A carrier tape made of pulp paper (e.g., Patent Literature 1) is inexpensive, but problems thereof are that individual pockets having a relatively small size are difficult to form, and that burrs (paper dust) are likely to be generated at cut surfaces when feed holes are formed by die-cutting. On the other hand, a carrier tape made of a resin is less likely to generate paper dust and can have various sizes of pockets; however, it is relatively poor in lightness in terms of the weight and is also disadvantageous in production costs because a heating process and a decompression (vacuuming) process are required when shaping the pockets.

### Citation List

### Patent Literature

Patent Literature 1: Japanese Patent Laid-Open No. 2000-43975

### SUMMARY OF INVENTION

### Technical Problem

It is an object of the present invention to provide a porous resin sheet that can be shaped without special processes such as heating and decompression while preventing generation of paper dust and a carrier tape including the same.

### Solution to Problem

In order to achieve the above object, the present inventors have intensively studied and, as a result, have found that a porous resin sheet that can be shaped without special processes such as heating and decompression while preventing generation of paper dust and a carrier tape including the same can be obtained by forming a porous resin sheet including a porous resin layer containing a thermoplastic resin, wherein the porous resin layer has a thickness and a porosity falling within their respective specific ranges and includes a substrate layer and a first surface layer, and wherein the substrate layer and the first surface layer each contain a thermoplastic resin and particles, and the content of the particles in the substrate layer and the content of the particles in the first surface layer fall within their respective specific ranges. This finding has led to the completion of the present invention.

Specifically, the present invention includes the following aspects.
<1> A porous resin sheet including a porous resin layer containing a thermoplastic resin, wherein
the porous resin layer has a thickness of 40 to 350 μm,
the porous resin layer has a porosity of 35 to 80%,
the porous resin layer includes a substrate layer and a first surface layer, and wherein
the substrate layer and the first surface layer each contain a thermoplastic resin and particles,
a content of the particles in the substrate layer is 20 to 45 mass %, and
a content of the particles in the first surface layer is 45 to 80 mass %.
<2> The porous resin sheet according to <1>, wherein
the first surface layer is a porous uniaxially-stretched resin layer, and
the substrate layer is a porous biaxially-stretched resin layer.
<3> The porous resin sheet according to <1> or <2>, wherein the first surface layer has a thickness of 5 μm or more.
<4> The porous resin sheet according to any one of <1> to <3>, wherein the first surface layer has a thickness of 10 μm or more.
<5> The porous resin sheet according to any one of <1> to <4>, wherein the porous resin layer further includes a second surface layer on a surface of the substrate layer opposite from the first surface layer.
<6> The porous resin sheet according to any one of <1> to <5> , wherein a ratio of a porosity of the first surface layer to a porosity of the substrate layer is 0.80 to 1.20.
<7> The porous resin sheet according to any one of <1> to <6>, having a rupture strength of 0.1 to 10 kgf/mm² in its width direction.
<8> The porous resin sheet according to any one of <1> to <7>, for use in carrier tapes.
<9> A carrier tape including:
the porous resin sheet according to any one of <1> to <8>, and
a pocket formed in the porous resin sheet.

### Advantageous Effect of Invention

The present invention can provide a porous resin sheet that can be shaped without special processes such as heating and decompression while preventing generation of paper dust and a carrier tape including the same.

### BRIEF DESCRIPTION OF DRAWINGS

FIG. 1 is a cross-sectional view of one mode of a porous resin sheet according to the present invention cut in the direction of the lamination.

FIG. 2 is a cross-sectional view of another mode of the porous resin sheet according to the present invention cut in the direction of the lamination.

FIG. 3 is a cross-sectional view of a porous resin sheet of a comparative example cut in the direction of the lamination.

FIG. 4 is a diagram showing a carrier tape including the porous resin sheet according to the other mode of the present invention, the diagram being a cross-sectional view of the carrier tape cut in the direction of the lamination across a pocket.

### DESCRIPTION OF EMBODIMENTS

Hereinbelow, a porous resin sheet according to the present invention will be described in detail. The following exemplifies the present invention, and the present invention is not limited thereto.

It should be noted that a numerical range represented by “A to B” herein refers to “A or more and B or less”.

The present invention relates to a porous resin sheet including a porous resin layer containing a thermoplastic resin, wherein the porous resin layer has a thickness of 40 to 350 μm and a porosity of 35 to 80% and includes a substrate layer and a first surface layer, and wherein the substrate layer and the first surface layer each contain a thermoplastic resin and particles, a content of the particles in the substrate layer is 20 to 45 mass %, and a content of the particles in the first surface layer is 45 to 80 mass %.

A carrier tape shaped without special processes such as heating and decompression while preventing generation of paper dust is obtained by using a porous resin sheet including a porous resin layer containing a thermoplastic resin, wherein the porous resin layer has a thickness and a porosity falling within their respective specific ranges and includes a substrate layer and a first surface layer, and wherein the substrate layer and the first surface layer each contain a thermoplastic resin and particles, and a content of the particles in the substrate layer and a content of the particles in the first surface layer fall within their respective specific ranges.

### Porous Resin Layer

The porous resin sheet according to the present invention includes a porous resin layer containing a thermoplastic resin, wherein the porous resin layer has a thickness of 40 to 350 μm and a porosity of 35 to 80% and includes a substrate layer and a first surface layer, and wherein the substrate layer and the first surface layer each contain a thermoplastic resin and particles, a content of the particles in the substrate layer is 20 to 45 mass %, and a content of the particles in the first surface layer is 45 to 80 mass %. Since the porous resin sheet includes such a porous resin layer, the weight of a carrier tape is likely to be reduced. Further, the increased porosity can provide spaces into which components such as the compressed resin and the particles can escape during shaping, thereby improving shapability.

### Thermoplastic Resin Contained in Porous Resin Layer

Since the porous resin layer contains a thermoplastic resin, generation of paper dust can be prevented, and in addition, water resistance is enhanced, thereby preventing a dimensional change caused by humidity, as compared to a case where pulp paper is used. The thermoplastic resin contained in the porous resin layer is not limited, and examples thereof include polyolefin-type resins such as a polyethylene resin and a polypropylene resin, a polyvinyl chloride resin, a polyethylene terephthalate resin, a polycarbonate resin, polymethylpentene-1, and a cyclic olefin. Another example of the thermoplastic resin contained in the porous resin layer is a mixture of two or more of these thermoplastic resins.

Among them, from a viewpoint that will be described later, polyolefin-type resins such as a polyethylene resin and a polypropylene resin are preferred, and a polyethylene resin and a polypropylene resin are more preferred. The thermoplastic resin preferably consists only of a polyolefin-type resin, and more preferably consists only of a polyethylene resin and a polypropylene resin.

The content of the thermoplastic resin in the porous resin layer is preferably 35 mass % or more, more preferably 40 mass % or more, even more preferably 45 mass % or more. Further, the content is preferably 80 mass % or less, more preferably 70 mass % or less, even more preferably 60 mass % or less. When the content of the thermoplastic resin is 35 mass % or more, the amount of paper dust generated is likely to be reduced and water resistance is likely to be improved.

### Polypropylene Resin

The use of a polypropylene resin for the porous resin layer is preferred because flexibility is imparted to the porous resin layer so that electronic parts or the like to be accommodated can easily be transported without being damaged.

Specific examples of the polypropylene resin include: propylene homopolymers such as an isotactic homopolypropylene resin obtained by homopolymerization of propylene and a syndiotactic homopolypropylene resin: propy lene/ethylene copolymers obtained by copolymerization of propylene as a main component with ethylene: propylene/α-olefin copolymers obtained by copolymerization of propylene as a main component with an α-olefin or the like such as 1-butene, 1-hexene, 1-heptene, 1-octene, or 4-methyl-1-pentene that is an alkylene having 4 or more carbon atoms; and propylene/ethylene/α-olefin copolymers mainly containing propylene. The propylene copolymer may either be a bipolymer or a multi-component polymer such as a terpolymer, and may be any one of a random copolymer, a block copolymer, and a reactor blended copolymer. More specific examples of the polypropylene resin include a propy lene homopolymer, a propylene/ethylene copolymer, a propylene/1-butene copolymer, a propylene/ethylene/1-butene copolymer, a propylene/4-methyl-1-pentene copolymer, a propylene/3-methyl-1-pentene copolymer, and a propylene/ethylene/3-methyl-1-pentene copolymer. Among them, in view of improving stretch-formability of the porous resin layer, a crystalline homopolypropylene resin obtained by homopolymerization of propylene is preferred, and an isotactic homopolypropylene resin is more preferred.

Specific examples of the polypropylene resin different in production method include polypropylene produced using a Ziegler-Natta polymerization catalyst, polypropylene produced using a metallocene-type polymerization catalyst (single-site polymerization catalyst), an olefin-type thermoplastic elastomer called also reactor TPO, and high-melt-strength polypropylene.

The melt flow rate (MFR) of the polypropylene resin measured in accordance with JIS K7210: 2014 (temperature: 230° C., load: 2.16 kg) is preferably 0.2 g/10 min or more, more preferably 1 g/10 min or more, even more preferably 2 g/10 min or more in view of improving the mechanical strength of the porous resin layer. The melt flow rate is preferably 20 g/10 min or less, more preferably 15 g/10 min or less, even more preferably 10 g/10 min or less, particularly preferably 6 g/10 min or less.

When the porous resin layer contains a polypropylene resin, the content of the polypropylene resin is preferably 15 mass % or more, more preferably 25 mass % or more, even more preferably 35 mass % or more. The content is preferably 80 mass % or less, more preferably 70 mass % or less, even more preferably 60 mass % or less.

### Polyethylene Resin

The use of a polyethylene resin for the porous resin layer can impart stretch-formability to the porous resin layer. A polyethylene resin may also be used in combination with another thermoplastic resin, and this case is preferred because stretch-formability of the polyethylene resin can be imparted in addition to the properties of another thermoplastic resin. For example, a polypropylene resin can be used in combination with a polyethylene resin as a resin component constituting the porous resin layer.

Examples of the polyethylene resin that can be used include a high-density polyethylene resin, a middle-density polyethylene resin, a linear low-density polyethylene resin, and a copolymer mainly containing ethylene.

When the porous resin layer contains a polyethylene resin, the content of the polyethylene resin is preferably 1 mass % or more, more preferably 3 mass % or more, even more preferably 5 mass % or more. The content is preferably 20 mass % or less, more preferably 15 mass % or less, even more preferably 10 mass % or less.

When the porous resin layer contains both a polypropylene resin and a polyethylene resin, the mass ratio between them (polypropylene resin: polyethylene resin) is preferably 1:99 to 99:1, more preferably 10:90 to 97:3, even more preferably 65:35 to 95:5, in view of pore formability.

### Particles Contained in Porous Resin Layer

As will be described later, since the substrate layer and the first surface layer included in the porous resin layer each contain particles, the porous resin layer contains particles. By stretching a resin composition containing particles, a porous resin layer having many pores formed therein can easily be obtained.

The porous resin layer is preferably a porous stretched resin layer obtained by stretching a resin containing particles.

The particles that can be used are not limited, and examples thereof include organic particles and inorganic particles. Among them, inorganic particles are preferably used, in view of preventing shape recovery after compression by press for shaping. The particles may be surface-treated particles.

Examples of the inorganic particles that can be used for the porous resin layer include calcium carbonate, titanium oxide, baked clay, talc, barium sulfate, aluminum sulfate, silica, zinc oxide, magnesium oxide, and diatomaceous earth. By adding inorganic particles, a porous resin layer having pores therein can easily be formed. Among them, a fine powder of calcium carbonate, clay, and diatomaceous earth are preferred because they are inexpensive and have excellent pore formability. Particularly, a fine powder of calcium carbonate is preferred for the following reasons: there are various types of products thereof, and therefore the porosity and the color of the porous resin layer can easily be adjusted.

The average particle size of the particles is preferably 0.05 μm or more, more preferably 0.1 μm or more, even more preferably 0.5 μm or more. The average particle size is preferably 6 μm or less, more preferably 4 μm or less, even more preferably 2 μm or less. When the average particle size falls within the above range, the porosity can easily be controlled to fall within a desired range.

The average particle size of the particles is a volume-average particle size (D50) measured by a laser diffraction particle size distribution analyzer.

The content of the particles in the porous resin layer is preferably 25 mass % or more, more preferably 30 mass % or more, even more preferably 35 mass % or more. The content is preferably 80 mass % or less, more preferably 70 mass % or less, even more preferably 60 mass % or less.

When the content of the particles in the porous resin layer is 25 mass % or more, a high porosity can easily be achieved due to pores formed by the particles serving as their origins during stretching, thereby easily achieving a large shaping depth appropriate to the size of an electronic part to be accommodated. When the content is 80 mass % or less, flexibility suitable for production and transport is easily maintained.

### Additives Optionally Contained in Porous Resin Layer

If necessary, the porous resin layer may contain an additive such as a heat stabilizer (antioxidant), a light stabilizer, an electrically conductive filler, a dispersant, or a lubricant.

When the porous resin layer contains a heat stabilizer, the content of the heat stabilizer is usually 0.001 to 1 mass %. Examples of the heat stabilizer include a sterically hindered phenol-type heat stabilizer, a phosphorus-type heat stabilizer, and an amine-type heat stabilizer.

When the porous resin layer contains a light stabilizer, the content of the light stabilizer is usually 0.001 to 1 mass %. Examples of the light stabilizer include a sterically hindered amine-type light stabilizer, a benzotriazole-type light stabilizer, and a benzophenone-type light stabilizer.

The dispersant or the lubricant can be used for the purpose of, for example, dispersing the particles. The amount of the dispersant or the lubricant used in the porous resin layer is usually in the range of 0.01 to 4 mass %. Examples of the dispersant or the lubricant include a silane coupling agent, a higher fatty acid such as oleic acid or stearic acid, metal soap, polyacrylic acid, polymethacrylic acid, and salts thereof.

Among them, a dispersant or a lubricant is preferably used for the following reason: they can prevent aggregation of the particles contained in the porous resin layer to increase the surface area, thereby enhancing pore-forming efficiency, and thus a porosity in proportion to the content of the particles is likely to be achieved even when the particles are contained in a large amount.

When the porous resin sheet including a porous resin layer is used as a carrier tape for electronic parts, an electrically conductive filler may be used to prevent adhesion of dust due to static electricity.

### Properties of Porous Resin Layer

### Thickness

The thickness of the porous resin layer is 40 to 350 μm. The thickness is preferably 80 μm or more, more preferably 100 μm or more, even more preferably 120 μm or more. The thickness is preferably 300 μm or less, more preferably 250 μm or less, even more preferably 225 μm or less.

The thickness of the porous resin layer can appropriately be changed within the above range according to the size of an article to be accommodated in a pocket or the like to be formed by shaping.

If the thickness of the porous resin layer is less than 40 μm, it is difficult to ensure a sufficient depth for shaping appropriate to the size of a part to be accommodated. On the other hand, if the thickness of the porous resin layer exceeds 350 μm, it is difficult to maintain flexibility suitable for production and transport.

The “thickness” of a layer herein refers to a value measured in accordance with JIS K7130: 1999. When the porous resin layer has a multi-layer laminate structure, the overall thickness of two or more layers is defined as the thickness of the multi-layer laminate structure. The thickness of each of the layers in the multi-layer laminate structure is calculated from the thickness of the multi-layer laminate structure measured above and the thickness ratio of each of the layers. The thickness ratio of each of the layers is determined by observing the cross-section of the multi-layer laminate structure with an electron microscope and identifying the interface between the layers from external appearance.

### Porosity

The porosity of the porous resin layer is 35 to 80%. The porosity is preferably 40% or more, more preferably 45% or more. The porosity is preferably 70% or less, more preferably 60% or less.

It should be noted that the “Porosity” of a layer herein refers to the proportion of the volume (volume ratio) of pores in the layer to the volume of the layer.

If the porosity is less than 35%, there is a fear that the porous resin layer does not have sufficient conformability to a shape formed by shaping without special processes such as heating and decompression. In such a case, for example, when a shape, such as a pocket having side walls and a bottom respectively perpendicular and parallel to the surface of the porous resin sheet including a porous resin layer, is formed by shaping, forming defects are likely to occur. For example, the side walls of the pocket or the like are tapered and the bottom undulates. When the porosity is 35% or more, deep shaping can easily be performed without special processes such as heating and decompression. On the other hand, if the porosity exceeds 80%, sufficient mechanical strength cannot be achieved.

It should be noted that the “conformability” herein refers to a property such that a resin deformed by shaping does not repel to return to a state before shaping so that a shape after shaping is stably maintained.

The porosity of the porous resin layer can be adjusted by, for example, a method in which the porosity of each of the substrate layer, the first surface layer, and an optional second surface layer, which will be described later, are adjusted to regulate the overall porosity of the porous resin layer.

A method for measuring the porosity of the porous resin layer is not limited, and for example, the porosity can be obtained in the following manner: a cut surface of the porous resin layer is observed with an electron microscope, and in the observed region in the cross-sectional photograph obtained, the proportion of the area (area ratio) occupied by pores in the porous resin layer is calculated as the porosity. When the porous resin layer has a multi-layer laminate structure, the overall porosity of the porous resin layer can be obtained by calculating the porosity of each of the layers and determining an average of the porosities of the respective layers weighted by thickness.

### Layered Structure of Porous Resin Layer

The porous resin layer may consist only of the substrate layer and the first surface layer or may be constituted from three or more layers. When constituted from three or more layers, the porous resin layer may include, for example, the substrate layer and the first surface layer as well as a second surface layer, which will be described later.

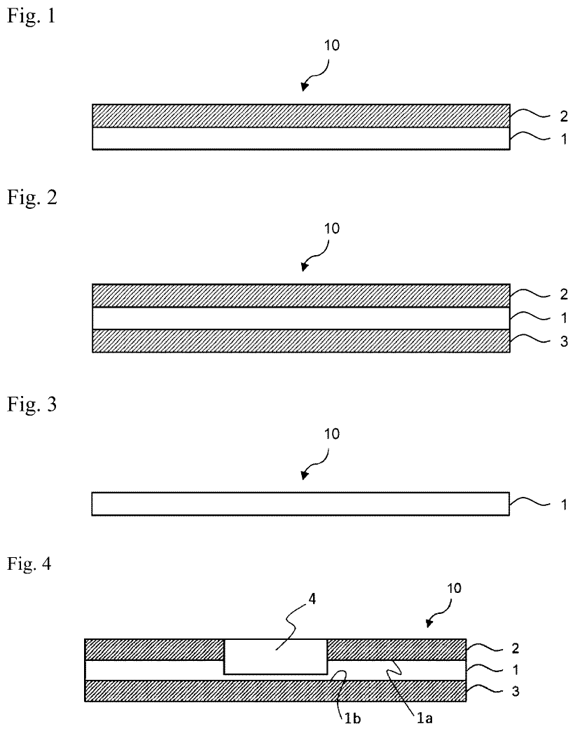

A first mode of the porous resin layer has a cross-section shown in FIG. 1 when cut in the direction of the lamination. In FIG. 1, a porous resin layer 10 consists only of a substrate layer 1 and a first surface layer 2.

A second mode of the porous resin layer has a cross-section shown in FIG. 2 when cut in the direction of the lamination. In FIG. 2, a porous resin layer 10 is constituted from a substrate layer 1, a first surface layer 2, and a second surface layer 3. Here, the second surface layer 3 is provided on the surface of the substrate layer 1 opposite from the first surface layer 2.

It should be noted that the drawings referred herein are intended to schematically show the positional relationship between the respective layers or between the layers and a pocket or the like, and are therefore not intended to show accurate thickness or width of each of the layers or an accurate size of the pocket or the like.

The porous resin layer is not limited to the above-described modes, and may include, for example, an additional layer between the substrate layer and the first surface layer and/or between the substrate layer and the second surface layer. When the porous resin layer includes an additional layer, the additional layer is not limited as long as it has s porous structure. For example, the additional layer may have a porosity of 10% or more.

### Substrate Layer

The porous resin layer of the porous resin sheet according to the present invention includes a substrate layer. The substrate layer imparts mechanical strength necessary for transport or the like to the porous resin sheet and provides spaces such as pockets when the porous resin sheet is shaped to form pockets or the like for accommodating electronic parts.

When the porous resin sheet is shaped to form pockets or the like, it is preferred that the pockets or the like should not penetrate the substrate layer. Further, when one of two interfaces that the substrate layer has is pressed down for forming the pockets or the like by shaping, the position of the other interface opposite from the one pressed down does not change as comparing the positions before and after the pockets or the like are formed by shaping with each other.

### Materials Constituting Substrate Layer

The substrate layer contains a thermoplastic resin and particles. Unless otherwise specified, the same materials as those described above for the porous resin layer can be used as materials for constituting the substrate layer, and preferences thereof are also the same.

### Thermoplastic Resin

The substrate layer contains a thermoplastic resin. Unless otherwise specified, preferences of the thermoplastic resin are the same as those described above for the porous resin layer.

The content of the thermoplastic resin in the substrate layer is preferably 35 mass % or more, more preferably 40 mass % or more, even more preferably 45 mass % or more, particularly preferably 50 mass % or more, most preferably 55 mass % or more. The content is preferably 85 mass % or less, more preferably 80 mass % or less, even more preferably 75 mass % or less, particularly preferably 70 mass % or less.

### Particles

The substrate layer contains particles. Unless otherwise specified, preferences of the particles are the same as those described above with reference to the porous resin layer.

The content of the particles in the substrate layer is 20 mass % or more, preferably 25 mass % or more, more preferably 30 mass % or more. The content is 45 mass % or less, preferably less than 45 mass %, more preferably 40 mass % or less, even more preferably 35 mass % or less.

If the content of the particles in the substrate layer is less than 20 mass %, the amount of pores formed by stretching is reduced so that it is difficult to achieve a large shaping depth appropriate to the size of an electronic part to be accommodated. On the other hand, if the content exceeds 45 mass %, it is difficult to maintain flexibility suitable for production and transport.

Particularly, when the content of inorganic particles is 45 mass % or less, compression of the porous resin layer is likely to be caused by shaping thereby to easily achieve a shaping depth, which is preferred.

### Properties of Substrate Layer

### Thickness

The thickness of the substrate layer is preferably 35 μm or more, more preferably 70 μm or more, even more preferably 90 μm or more, particularly preferably 110 μm or more. The thickness is preferably 300 μm or less, more preferably 250 μm or less, even more preferably 200 μm or less, particularly preferably 190 μm or less. The substrate layer is preferably larger in thickness than both the first surface layer and the second surface layer, which will be described later.

A thickness of the substrate layer of 35 μm or more is preferred because it makes it easy to achieve a sufficient depth for shaping appropriate to the size of a part to be accommodated. A thickness of 300 μm or less is preferred because it makes it easy to maintain flexibility suitable for production and transport.

A method for measuring the thickness of the substrate layer may be the same as the method for measuring the thickness of the porous resin layer.

### Porosity

The porosity of the substrate layer is preferably 35% or more, more preferably 40% or more, even more preferably 45% or more. The porosity is preferably 80% or less, more preferably 70% or less, even more preferably 60% or less.

A porosity of the substrate layer of 35% or more is preferred for the following reason: even when a deep shape is formed by shaping, sufficient conformability to the shape is obtained so that the shapes of a bottom and side walls formed by shaping are likely to be stabilized. A porosity of 80% or less is preferred because the porous resin sheet is likely to have sufficient mechanical strength.

The porosity of the substrate layer can be adjusted by the particle content in the substrate layer, the average particle size, the composition of the thermoplastic resin, stretching conditions, etc.

A method for measuring the porosity of the substrate layer may be the same as the method for measuring the porosity of the porous resin layer.

### Stretching

The substrate layer is preferably stretched and is more preferably biaxially stretched.

Since the substrate layer contains particles, pores can easily be formed in the substrate layer by stretching. In the case of biaxial stretching, a high porosity can be achieved even when the particle content is smaller, and the shape is thus likely to be stabilized even when a deep shape is formed by shaping, which is preferred. Further, stiffness is imparted by biaxial stretching, and thus problems are less likely to occur in the process of transport or the like even though the substrate layer has a porous structure, which is preferred.

### First Surface Layer

The porous resin layer of the porous resin sheet according to the present invention includes a first surface layer. The first surface layer is the outermost layer of the porous resin layer and located on the side on which pockets or the like of a carrier tape are formed by shaping. Since the porous resin sheet includes a first surface layer having a high particle content, it is easy to prevent side walls of the pockets or the like from being tapered during shaping.

### Materials Constituting First Surface Layer

The first surface layer contains a thermoplastic resin and particles. Unless otherwise specified, the same materials as those described above for the porous resin layer can be used as materials for constituting the first surface layer, and preferences thereof are also the same.

### Thermoplastic Resin

The first surface layer contains a thermoplastic resin. Unless otherwise specified, preferences of the thermoplastic resin are the same as those described above for the porous resin layer.

The content of the thermoplastic resin in the first surface layer is preferably 10 mass % or more, more preferably 20 mass % or more, even more preferably 30 mass % or more. The content is preferably 50 mass % or less, more preferably 45 mass % or less, even more preferably 40 mass % or less.

A thermoplastic resin content in the first surface layer of 10 mass % or more is preferred because rupture during forming is likely to be prevented. A thermoplastic resin content to 50 mass % or less is preferred because it is possible to prevent the resin from repelling during shaping. For example, when a pocket or the like having side walls and a bottom respectively perpendicular and parallel to the surface of the porous resin sheet is formed by shaping, deformation of the porous resin sheet is easily triggered by rupture so that the side walls of the pocket or the like are prevented from being tapered during shaping, and also the shape of the bottom is likely to be stabilized, which are preferred.

### Particles

The first surface layer contains particles. Unless otherwise specified, preferences of the particles are the same as those described above for the porous resin layer.

The content of the particles in the first surface layer is 45 mass % or more, preferably 50 mass % or more, more preferably 55 mass % or more. The content is 80 mass % or less, preferably 75 mass % or less, more preferably 70 mass % or less, even more preferably 65 mass % or less.

If the particle content in the first surface layer is less than 45 mass %, it is difficult to control the shapes of side walls and a bottom of the pocket or the like during shaping a pocket or the like. On the other hand, when the particle content in the first surface layer is 45 mass % or more, the side walls are prevented from being tapered during shaping and the shape of the bottom is likely to be stabilized, in a case where, for example, a pocket or the like having side walls and a bottom respectively perpendicular and parallel to the surface of the porous resin sheet is formed by shaping. This results from the fact that at the boundary between an area against which a shaping die is pressed and an area against which the shaping die is not pressed, rupture is more likely to occur at the interface between the particles or the interface between the particle and the thermoplastic resin than the thermoplastic resin. The particles are preferably inorganic particles because the above-described tendency is remarkable for the shape of the side walls and the shape of the bottom during shaping.

On the other hand, if the particle content exceeds 80 mass %, rupture is likely to occur during sheet forming.

### Properties of First Surface Layer

### Thickness

The thickness of the first surface layer is preferably 5 μm or more, more preferably 10 μm or more, even more preferably 13 μm or more, particularly preferably 15 μm or more, most preferably 18 μm or more. The thickness is preferably 50 μm or less, more preferably 40 μm or less, even more preferably 35 μm or less, particularly preferably 30 μm or less, most preferably 25 μm or less.

A thickness of the first surface layer of 5 μm or more is preferred for the following reason: when a pocket or the like is formed by shaping, the strain can be averaged in the area including the first surface layer and part of the substrate layer where the bottom of the pocket or the like is formed by compression with a die, and therefore the shape of the compressed porous resin layer is stabilized at the bottom of the pocket or the like so that the shape is likely to be stabilized during shaping. A thickness of 50 um or less is preferred because a deep shape is easily formed by shaping.

A method for measuring the thickness of the first surface layer may be the same as the method for measuring the thickness of the porous resin layer.

The ratio of the thickness of the first surface layer to the thickness of the substrate layer is preferably 0.03 or more, more preferably 0.05 or more, even more preferably 0.07 or more. The thickness ratio is preferably 0.5 or less, more preferably 0.3 or less, even more preferably 0.2 or less.

A ratio of the thickness of the first surface layer to the thickness of the substrate layer of 0.03 or more is preferred because the resin is less likely to repel during shaping to easily stabilize the shape. A thickness ratio of 0.5 or less is preferred because a deep shape is easily formed by shaping.

### Porosity

The porosity of the first surface layer is preferably 35% or more, more preferably 40% or more, even more preferably 45% or more. The porosity is preferably 80% or less, more preferably 70% or less, even more preferably 60% or less.

A porosity of the first surface layer of 35% or more is preferred for the following reason: even when a deep shape is formed by shaping, sufficient conformability to the shape is obtained so that the shapes of a bottom and side walls formed by shaping are likely to be stabilized. A porosity of 80% or less is preferred because the sheet is likely to have sufficient mechanical strength.

The porosity of the first surface layer can be adjusted by the particle content in the first surface layer, the average particle size, the composition of the thermoplastic resin, stretching conditions, etc.

A method for measuring the porosity of the first surface layer may be the same as the method for measuring the porosity of the porous resin layer.

The ratio of the porosity of the first surface layer to the porosity of the substrate layer is preferably 0.80 or more, more preferably 0.85 or more, even more preferably 0.90 or more. The porosity ratio is preferably 1.20 or less, more preferably 1.15 or less, even more preferably 1.10 or less.

When the ratio of the porosity of the first surface layer to the porosity of the substrate layer falls within such a range, a difference in a shape formed by shaping between the surface layer and the substrate layer is reduced, and also, when a pocket or the like having side walls and a bottom respectively perpendicular and parallel to the surface of the porous resin sheet is formed by shaping, the side walls of the pocket or the like can be prevented from being tapered, which are preferred.

### Stretching

The first surface layer is preferably stretched and is more preferably uniaxially stretched. Because resin chains are oriented in a stretching direction, the first surface layer is easily ruptured along the stretching direction during shaping, and a shape formed by shaping along the stretching direction can be stabilized, which are preferred.

Further, since the first surface layer contains particles, pores elongated along the stretching direction are formed by uniaxially stretching the first surface layer so that the first surface layer is more easily ruptured along the stretching direction during shaping, and a shape formed by shaping along the stretching direction can also be stabilized, which are preferred. Particularly, when a pocket or the like whose longitudinal direction is parallel to the stretching direction is formed by shaping, pores elongated along the stretching direction advantageously respond to shaping.

The “longitudinal direction of a pocket or the like” herein refers to the direction of the long axis of a pocket or the like having any shape whose aspect ratio is not 1:1, and the “shorter direction of a pocket or the like” refers to the direction of the short axis of a pocket or the like having any shape whose aspect ratio is not 1:1.

The first surface layer and the substrate layer, which are both contain particles, are uniaxially stretched and biaxially stretched, respectively. In this way, it is possible to obtain a porous resin layer including a porous uniaxially-stretched resin layer as a first surface layer and a porous biaxially-stretched resin layer as a substrate layer.

Such a layered structure is preferred for the following reason: when a pocket or the like having side walls and a bottom respectively perpendicular and parallel to the surface of the porous resin sheet is formed by shaping, it is possible to prevent forming defects such that the side walls of the pocket or the like are tapered and the bottom undulates.

A porous resin layer including a porous uniaxially-stretched resin layer as a first surface layer and a porous biaxially-stretched resin layer as a substrate layer can be produced through, for example, the following steps.
Step 1: uniaxially stretching a resin sheet for a substrate layer to obtain a porous uniaxially-stretched resin layer.
Step 2: laminating a resin sheet for a first surface layer on the porous uniaxially-stretched resin layer obtained in step 1 to obtain a laminated sheet.
Step 3: uniaxially stretched the laminated sheet obtained in step 2 in a direction orthogonal to the stretching direction in step 1 to obtain a porous resin layer including a porous uniaxially-stretched resin layer as a first surface layer and a porous biaxially-stretched resin layer as a substrate layer.

### Second Surface Layer

The porous resin layer of the porous resin sheet according to the present invention may further include a second surface layer on the surface of the substrate layer opposite from the first surface layer. The second surface layer is the outermost layer of the porous resin layer and opposite from the surface in which a pocket or the like is to be formed by shaping the porous resin sheet according to the present invention.

The second surface layer is preferably included in the porous resin layer because the bottom of a shape formed by shaping is stabilized.

### Materials Constituting Second Surface Layer

Unless otherwise specified, the same materials as those described above for the porous resin layer can be used as materials for constituting the second surface layer, and preferences thereof are also the same.

### Particles

The second surface layer may contain particles. Unless otherwise specified, preferences of the particles are the same as those described above for the porous resin layer.

When the second surface layer contains particles, the content of the particles is preferably 40 mass % or more, more preferably 45 mass % or more, even more preferably 50 mass % or more, particularly preferably 55 mass % or more. The content is preferably 80 mass % or less, more preferably 75 mass % or less, even more preferably 70 mass % or less, particularly preferably 65 mass % or less.

A particle content in the second surface layer of 40 mass % or more is preferred because pores easily appear by stretching. A particle content of 80 mass % or less is preferred because the rupture strength of the film is maintained.

### Properties of Second Surface Layer

### Thickness

The thickness of the second surface layer is preferably 5 μm or more, more preferably 7 μm or more, even more preferably 10 μm or more. The thickness is preferably 50 μm or less, more preferably 40 μm or less, even more preferably 30 μm or less.

A thickness of the second surface layer of 5 μm or more is preferred because the second surface layer serves as a receptive layer for the compressed first surface layer and substrate layer in an area subjected to press for shaping.

A method for measuring the thickness of the second surface layer may be the same as the method for measuring the thickness of the porous resin layer.

### Porosity

The porosity of the second surface layer is preferably 35% or more, more preferably 40% or more, even more preferably 45% or more. The porosity is preferably 80% or less, more preferably 70% or less, even more preferably 60% or less.

A porosity of the second surface layer of 35% or more is preferred for the following reason: even when a deep shape is formed by shaping, sufficient conformability to the shape is obtained so that the shapes of a bottom and side walls formed by shaping are likely to be stabilized. A porosity to 80% or less is preferred because the porous resin sheet is likely to have sufficient mechanical strength.

The porosity of the second surface layer can be adjusted by the particle content in the first surface layer, the average particle size, the composition of the thermoplastic resin, stretching conditions, etc.

A method for measuring the porosity of the second surface layer may be the same as the method for measuring the porosity of the porous resin layer.

### Stretching

The second surface layer is preferably stretched and is more preferably uniaxially stretched.

When the second surface layer is uniaxially stretched, mechanical strength is improved in the uniaxial direction, and thus, shape stability is likely to be obtained after a pocket or the like is formed by shaping, which is preferred.

A porous resin layer including porous uniaxially-stretched resin layers as a first surface layer and a second surface layer and a porous biaxially-stretched resin layer as a substrate layer can be produced through, for example, the following steps.
Step 1: uniaxially stretching a resin sheet for a substrate layer to obtain a porous uniaxially-stretched resin layer.
Step 2: laminating a resin sheet for a first surface layer on the porous uniaxially-stretched resin layer obtained in step 1, and laminating a resin sheet for a second surface layer on the surface of the porous uniaxially-stretched resin layer opposite from the resin sheet for a first surface layer to obtain a laminated sheet.
Step 3: uniaxially stretching the laminated sheet obtained in step 2 in a direction orthogonal to the stretching direction in step 1 to obtain a porous resin layer including porous uniaxially-stretched resin layers as a first surface layer and a second surface layer and a porous biaxially-stretched resin layer as a substrate layer.

### Method for Producing Porous Resin Layer, Substrate Layer, First Surface Layer, and Second Surface Layer

A method for producing a porous resin layer, a substrate layer, a first surface layer, and a second surface layer is not limited and may be a conventional method. Examples of the method include cast molding in which a melt resin is extruded as a sheet through a T die, an I die, or the like connected to a screw extruder, calendar molding, roll molding, and inflation molding. When a porous resin layer having a multi-layer laminate structure is produced, a substrate layer, a first surface layer, and an optional second surface layer may separately be produced and then laminated by a lamination method. Alternatively, film formation for respective layers and lamination of the films may be performed at the same time using a conventional method such as a multi-layer die method involving use of a feed block or a multi-manifold or an extrusion lamination method involving use of a plurality of dies.

A porous resin sheet can be produced by laminating a porous resin layer and another optional layer.

When the porous resin layer, the substrate layer, the first surface layer, and the optional second surface layer are stretched, the substrate layer may be stretched either before or after the first surface layer and the optional second surface layer are laminated thereon.

As one mode, a porous resin layer including porous uniaxially-stretched resin layers as a first surface layer and an optional second surface layer and a porous biaxially-stretched resin layer as a substrate layer can be produced through, for example, the above steps.

Examples of a stretching method include machine-direction stretching in which the difference in circumferential velocity between rolls is applied, transverse stretching involving use of a tenter oven, sequential biaxial stretching in which machine-direction stretching and transverse stretching are performed in combination, rolling, simultaneous biaxial stretching in which a tenter oven and a pantograph are used in combination, and simultaneous biaxial stretching in which a tenter oven and a linear motor are used in combination. Alternatively, simultaneous biaxial stretching (inflation molding) may be used in which a melt resin is extruded and molded to form a tube with the use of a circular die connected to a screw extruder, and then air is blown into the tube.

Among them, the porous resin layer, the substrate layer, the first surface layer, and the second surface layer are preferably produced by extruding a resin composition into a sheet through a T die connected to an extruder and then stretching the sheet, in view of easily achieving multi-layering and easily adjusting a film thickness. Examples of a stretching method include machine-direction stretching, transverse stretching, and sequential biaxial stretching or simultaneous biaxial stretching in which machine-direction stretching and transverse stretching are performed in combination.

When an amorphous resin is used as a thermoplastic resin, a stretching temperature at which stretching is performed is preferably equal to or higher than the glass transition temperature of the thermoplastic resin. When a crystalline resin is used as a thermoplastic resin, the stretching temperature is preferably equal to or higher than the glass transition temperature of a non-crystalline portion of the thermoplastic resin and equal to or lower than the melting point of a crystalline portion of the thermoplastic resin, and is preferably lower by 2 to 60° C. than the melting point of the thermoplastic resin. Specifically, in the case of a propylene homopolymer (melting point: 155 to 167° C.), the stretching temperature is preferably 100 to 164° C., and in the case of a high-density polyethylene resin (melting point: 121 to 134° C.), the stretching temperature is preferably 70 to 133° C. Particularly, in view of achieving a higher porosity, the stretching temperature at the time when a crystalline resin is used as a thermoplastic resin is preferably lower by 20° C. or more than the melting point of the thermoplastic resin and is more preferably lower by 25° C. or more than the melting point of the thermoplastic resin. It should be noted that the stretching temperature may be set on the basis of the glass transition temperature or the melting point of a thermoplastic resin mainly used (e.g., a thermoplastic resin used in an amount of 50 mass % or more of the total mass of all the thermoplastic resins used).

A stretching speed is not limited but is preferably in the range of 20 to 350 m/min in view of stable stretch-forming.

A draw ratio can also be appropriately set in consideration of the properties of a thermoplastic resin to be used etc. For example, when a propylene homopolymer or a propylene copolymer is used, the draw ratio for uniaxial stretching is usually 1.1 or more, preferably 2 or more, for the lower limit, and the draw ratio is usually 10 or less, preferably 9 or less, for the upper limit. On the other hand, the draw ratio for biaxial stretching is usually 1.5 or more, preferably 4 or more, for the lower limit, in terms of area draw ratio, and the draw ratio is usually 75 or less, preferably 50 or less in terms of area draw ratio, for the upper limit. When another thermoplastic resin film is stretched in one direction, the draw ratio is usually 1.2 or more, preferably 2 or more, for the lower limit, and the draw ratio is usually 10 or less, preferably 5 or less, for the upper limit. The draw ratio for biaxially stretching is usually 1.5 or more, preferably 4 or more in terms of area draw ratio, for the lower limit, and the draw ratio is usually 20 or less, preferably 12 or less in terms of area draw ratio, for the upper limit. When the draw ratio is within the above range, desired porosity and grammage are likely to be achieved, and opacity is likely to be improved. Further, film rupture is less likely to occur so that stretch-forming is likely to be stabilized. When the particles serve as origins of pores formed in the porous resin layer by stretching, all the draw ratio, the stretching temperature, and the particle content preferably satisfy their respective specific requirements described above to allow the porous resin layer to have a high porosity.

### Porous Resin Sheet

The porous resin sheet according to the present invention includes the above-described porous resin layer.

### Properties of Porous Resin Sheet

### Rupture Strength

The rupture strength of the porous resin sheet in its width direction is preferably 0.1 kgf/mm² or more, more preferably 1.0 kgf/mm² or more, even more preferably 2.0 kgf/mm² or more. The rupture strength in the width direction is preferably 10 kgf/mm² or less, more preferably 8 kgf/mm² or less, even more preferably 6 kgf/mm² or less.

The “rupture strength of the porous resin sheet in its width direction” herein refers to rupture strength measured by pulling the porous resin sheet in its width direction (TD). The rupture strength can be measured in accordance with, for example, JIS-K7127: 1999.

A rupture strength of the porous resin sheet in its width direction of 0.1 kgf/mm² or more is preferred in view of maintaining a film shape during transport. A rupture strength in the width direction of 10 kgf/mm² or less is preferred in view of maintaining a shape formed by press shaping.

There is a case where the pockets or the like are generally formed in such a manner that the longitudinal direction of each of the pockets or the like is parallel to the width direction of the carrier tape in order to increase the number of pockets or the like per unit length of a carrier tape. For this reason, the porous resin sheet is preferably designed to have such a rupture strength as described above in its width direction.

When the pockets or the like are formed in such a manner that the longitudinal direction of each of the pockets or the like is parallel to the length direction of the carrier tape, the porous resin sheet may be designed to have such a rupture strength as described above in its length direction.

### Intended Uses

The porous resin sheet according to the present invention has properties suitable for forming a carrier tape. Therefore, the porous resin sheet according to the present invention is preferably used for carrier tapes.

For example, a carrier tape can be formed which includes the porous resin sheet described above and pockets formed in the porous resin sheet. Each of the pockets may have a size (length×width) of, for example, 0.1×0.1 mm to 3×3 mm.

FIG. 4 is a cross-sectional view of a carrier tape including one mode of the porous resin sheet according to the present invention, the carrier tape being cut in the direction of the lamination taken across a pocket. As shown in FIG. 4, it is preferred that a pocket 4 should not penetrate the substrate layer 1. Further, it is more preferred that when interfaces 1a, among two interfaces 1a and 1b that the substrate layer 1 has, is pressed down for forming the pocket 4 by shaping, the position of the interface 1b, which is opposite from the interface interfaces 1a pressed down, does not change as comparing its positions before and after the pocket 4 is formed by shaping with each other. On the other hand, it is preferred that the interface 1a of the carrier tape, at which a pocket or the like is to be formed by shaping, is linear or almost linear in the cross-section of the carrier tape taken across the pocket.

The carrier tape including the porous resin sheet according to the present invention may further include another necessary member such as a cover tape.

The carrier tape formed including the porous resin sheet according to the present invention can suitably be used as a carrier tape for accommodating parts. Examples of the parts include electronic parts.

### Method for Shaping Porous Resin Sheet

A method for shaping the porous resin sheet to form a pocket or the like is not limited, and examples thereof include pressure forming, press forming, and vacuum rotary forming.

Among them, the porous resin sheet is preferably shaped by press forming at ordinary temperature, in view of costs etc.

A shape formed in the porous resin sheet by shaping is selected according to the shape of a part to be accommodated therein. Examples of the shape include, but not limited to, a cylindrical shape and a rectangular-column shape.

### EXAMPLES

Hereinbelow, the present invention will more specifically be described by way of Examples, but the present invention is not limited to the following Examples.

### Resin Composition

Materials of each of resin compositions used in Examples and Comparative Examples and formulations thereof are as shown in Table 1.

TABLE 1

| | | A | B | C | D |
|---|---|---|---|---|---|
| Resin composition | | [mass %] | [mass %] | [mass %] | [mass %] |
| Propylene | manufactured by Japan Polypropylene | 59.7 | 49.5 | 36.5 | 54.4 |
| homopolymer | Corporation | | | | |
| | Trade name: NOVATEC PP FY4 | | | | |
| High-density | manufactured by Japan Polyethylene | 10.0 | 10.0 | 3.0 | 0.0 |
| polyethylene | Corporation | | | | |
| | Trade name: NOVATEC HD HJ360 | | | | |
| Calcium | manufactured by BIHOKU FUNKA | 30.0 | 40.0 | 60.0 | 45.0 |
| carbonate | KOGYO CO., LTD. | | | | |
| | Trade name: SOFTON #1800, | | | | |
| | Average particle size: 1.2 μm | | | | |
| Dispersant | manufactured by Kao Chemicals, Trade | 0.3 | 0.5 | 0.5 | 0.6 |
| | name: LUNAC OV | | | | |

### Porous Resin Sheet

### Example 1

The resin composition A was kneaded in an extruder set at 230° C. and then supplied into an extrusion die set at 250° C. to extrude into a sheet, and the sheet was cooled with a cooling device to obtain an unstretched sheet. This unstretched sheet was heated to 130° C. and stretched to a draw ratio of four in its machine direction (length direction) using a plurality of rolls different in circumferential velocity to obtain a stretched film with a draw ratio of four. Then, the resin composition C was kneaded in an extruder set at 250° C. and then supplied into an extrusion die set at 250° C. to extrude into a sheet, and the sheet was laminated on the surface of the stretched film with a draw ratio of four prepared above to obtain a double-layer laminated film. Then, the laminated film was cooled to 60° C., then again heated to about 140° C., and stretched to a draw ratio of eight in its transverse direction (width direction) with the use of a tenter oven. Then, the stretched laminated film was subjected to annealing treatment in an oven adjusted to 160° C. and cooled to 60° C. Then, the edges of the stretched laminated film were removed by slitting to obtain a porous resin sheet having a double-layer structure (first surface layer/substrate layer: composition: resin composition C/resin composition A, porosity: 40.0%/49.0%, thickness: 15 μm/185 μm, stretching: uniaxial/biaxial), a thickness of 200 μm, and a porosity of 48.3%.

It should be noted that the properties of the obtained porous resin sheet were measured in the following manner.

### Overall Thickness

The overall thickness (μm) of the porous resin sheet was measured in accordance with JIS K7130: 1999 “Plastics—Film and Sheeting—Determination of thickness” with the use of a constant pressure thickness gauge (device name: PG-01J, manufactured by TECLOCK Co., Ltd.).

### Thickness of Each Layer

The thickness (μm) of each of the layers in the multi-layer laminate structure was measured in the following manner.

The porous resin sheet was cooled with liquid nitrogen to a temperature of −60° C. or lower, placed as a sample on a glass plate, and cut at a right angle with a razor blade (trade name: Proline Blade, manufactured by Schick Japan K. K.) to prepare a sample for cross-section measurement. The cross-section of the obtained sample was observed with a scanning electron microscope (device name: JSM-6490, manufactured by JEOL Ltd.), and the boundary between the layers was determined from their composition and external appearance to determine the thickness ratio of each of the layers in the porous resin sheet. The thickness of each of the layers was determined by multiplying the overall thickness measured above by the thickness ratio of each of the layers.

### Measurement of Porosity

The porosity (%) of each of the layers in the multi-layer laminate structure was measured in the following manner.

Part of the porous resin sheet randomly selected was cut and embedded in an epoxy resin, and the resultant was solidified. Then, the resultant was cut perpendicularly to the planar direction and TD direction of the porous resin sheet to be measured with the use of a microtome, and the resulting sample was attached to a sample table for observation so that the cut surface thereof was an observation surface. Gold or gold-palladium or the like was vapor-deposited onto the observation surface, the cut surface of the porous resin sheet was observed at any magnification (e.g., at a 500- to 3000-fold magnification) appropriate to observation with a scanning electron microscope, and the image of the observed region was taken as data. The obtained image data was subjected to image processing in an image analyzer to determine the area ratio (%) of pores in each of the layers of the porous resin sheet. The average of the area ratios (%) determined for 10 or more regions randomly selected was defined as the porosity (%) of each of the layers.

The average of the porosities of the respective layers weighted by thickness was determined as the porosity of all the layers.

### Example 2, Comparative Example 1, Comparative Example 4

A porous resin sheet of each of Example 2, Comparative Example 1, and Comparative Example 4 was obtained in the same manner as in Example 1 except that the resin compositions used, the thickness of each of the layers, and the porosity of each of the layers were changed as shown in Table 2 or Table 3.

### Example 3

A porous resin sheet of Example 3 was obtained in the same manner as in Example 1 except that the temperature during transverse-direction stretching (the temperature of the tenter oven) was changed to 145° C.

### Example 4

A porous resin sheet of Example 4 was obtained in the same manner as in Example 1 except that the temperature during machine-direction stretching was changed to 140° C.

### Comparative Example 2

A porous resin sheet of Comparative Example 2 was obtained in the same manner as in Example 2 except that the temperature during machine-direction stretching was changed to 145° C.

TABLE 2

| | | | Example | Example | Comparative | Example | Comparative | Example |
|---|---|---|---|---|---|---|---|---|
| | | | 1 | 2 | Example 1 | 3 | Example 2 | 4 |
| Porous | First | Resin composition | C | C | C | C | C | C |
| resin | surface | Porosity [%] | 40.0 | 40.0 | 40.0 | 20.0 | 40.0 | 40.0 |
| layer | layer | Thickness [μm] | 15 | 40 | 9 | 15 | 40 | 15 |
| | | Number of stretching | One axis | One axis | One axis | One axis | One axis | One axis |
| | | axes | | | | | | |
| | Substrate | Resin composition | A | A | A | A | A | A |
| | layer | Porosity [%] | 49.0 | 49.0 | 49.0 | 49.0 | 30.0 | 35.0 |
| | | Thickness[μm] | 185 | 160 | 20 | 185 | 160 | 185 |
| | | Number of stretching | Two | Two | Two axes | Two | Two axes | Two |
| | | axes | axes | axes | | axes | | axes |
| | Second | Resin composition | — | — | — | — | — | — |
| | surface | Porosity [%] | — | — | — | — | — | — |
| | layer | Thickness [μm] | — | — | — | — | — | — |
| | | Number of stretching | — | — | — | — | — | — |
| | | axes | | | | | | |

| | | | | | | |
|---|---|---|---|---|---|---|
| Porosity (overall) [%] | 48.3 | 47.2 | 46.2 | 46.8 | 32.0 | 35.4 |
| Thickness (overall) [μm] | 200 | 200 | 29 | 200 | 200 | 200 |
| Thickness ratio(surface | 0.08 | 0.25 | 0.45 | 0.08 | 0.25 | 0.08 |
| layer/substrate layer) | | | | | | |
| Porosity ratio(surface | 0.82 | 0.82 | 0.82 | 0.41 | 1.33 | 1.14 |
| layer/substrate layer) | | | | | | |

### Example 5

A porous resin sheet of Example 5 was obtained in the same manner as in Example 1 except that the resin compositions were changed as shown in Table 3 and that the temperature during transverse-direction stretching (the temperature of the tenter oven) was changed to 135° C.

### Comparative Example 3

The resin composition B was kneaded in an extruder set at 230° C. and then supplied into a feed block-type multi-layer die set at 250° C. to extrude into a sheet, and the sheet was cooled with a cooling device to obtain an unstretched sheet. This unstretched sheet was heated to 135° C. and stretched to a draw ratio of four in its machine direction to obtain a stretched film with a draw ratio of four. Then, this stretched film with a draw ratio of four was cooled to 60° C., again heated to about 135° C., and stretched to a draw ratio of eight in its transverse direction with the use of a tenter oven. Then, the stretched film was subjected to annealing treatment in an oven adjusted to 160° C. and cooled to 60° C. Then, the edges of the stretched film were removed by slitting to obtain a porous resin sheet having a single-layer structure shown in FIG. 3 (substrate layer: composition: resin composition B, porosity: 50.0%, thickness: 200 μm, stretching: biaxial), a total thickness of 200 μm, and a porosity of 50.0%.

### Example 6

The resin composition A was kneaded in an extruder set at 230° C. and then supplied into an extrusion die set at 250° C. to extrude into a sheet, and the sheet was cooled with a cooling device to obtain an unstretched sheet. This unstretched sheet was heated to 135° C. and stretched to a draw ratio of four in its machine direction using a plurality of rolls different in circumferential velocity to obtain a stretched film with a draw ratio of four. Then, the resin composition C was kneaded in an extruder set at 250° C. and then supplied into an extrusion die set at 250° C. to extrude into a sheet, and the sheet was laminated on each of the top and bottom surfaces of the stretched film with a draw ratio of four prepared above to obtain a three-layer laminated film. Then, the laminated film was cooled to 60° C., then again heated to about 135° C., and stretched to a draw ratio of eight in its transverse direction with the use of a tenter oven. Then, the stretched laminated film was subjected to annealing treatment in an oven adjusted to 160° C. and cooled to 60° C. Then, the edges of the stretched laminated film were removed by slitting to obtain a porous resin sheet having a three-layer structure (first surface layer/substrate layer/second surface layer: composition: resin composition C/resin composition A/resin composition C, porosity: 40.0%/50.0%/40.0%, thickness: 15 μm/170 μm/15 μm, stretching: uniaxial/biaxial/uniaxial), a thickness of 200 μm, and a porosity of 49.2%.

### Example 7

A porous resin sheet of Example 7 was obtained in the same manner as in Example 1 except that the resin composition A and the resin composition C were respectively extruded into sheets so that the thickness of the substrate layer was 190 μm and the thickness of the first surface layer was 10 μm.

### Example 8

A porous resin sheet of Example 8 was obtained in the same manner as in Example 1 except that the resin composition A and the resin composition C were respectively extruded into sheets so that the thickness of the substrate layer was 195 μm and the thickness of the first surface layer was 5 μm.

### Example 9

A porous resin sheet of Example 9 was obtained in the same manner as in Example 1 except that the resin compositions were changed as shown in Table 3 and that the temperature during transverse-direction stretching (the temperature of the tenter oven) was changed to 150° C.

### Example 10

A porous resin sheet of Example 3 was obtained in the same manner as in Example 1 except that the temperature during transverse-direction stretching (the temperature of the tenter oven) was changed to 130° C.

TABLE 3

| | | | Example | Comparative | Comparative | Example | Example | Example | Example | Example |
|---|---|---|---|---|---|---|---|---|---|---|
| | | | 5 | Example 3 | Example 4 | 6 | 7 | 8 | 9 | 10 |
| Porous | First | Resin | D | — | B | C | C | C | D | C |
| resin | surface | composition | | | | | | | | |
| layer | layer | Porosity [%] | 40.0 | — | 30.0 | 40.0 | 40.0 | 40.0 | 35.0 | 50.0 |
| | | Thickness | 15 | — | 15 | 15 | 10 | 5 | 15 | 15 |
| | | [μm] | | | | | | | | |
| | | Number of | One axis | — | One axis | One axis | One axis | One axis | One axis | One axis |
| | | stretching | | | | | | | | |
| | | axes | | | | | | | | |
| | Substrate | Resin | A | B | A | A | A | A | A | A |
| | layer | composition | | | | | | | | |
| | | Porosity [%] | 49.0 | 50.0 | 49.0 | 50.0 | 49.0 | 49.0 | 45.0 | 51.0 |
| | | Thickness | 185 | 200 | 185 | 170 | 190 | 195 | 185 | 185 |
| | | [μm] | | | | | | | | |
| | | Number of | Two | Two axes | Two axes | Two | Two | Two | Two | Two |
| | | stretching | axes | | | axes | axes | axes | axes | axes |
| | | axes | | | | | | | | |
| | Second | Resin | — | — | — | C | — | — | — | — |
| | surface | composition | | | | | | | | |
| | layer | Porosity[%] | — | — | — | 40.0 | — | — | — | — |
| | | Thickness | — | — | — | 15 | — | — | — | — |
| | | [μm] | | | | | | | | |
| | | Number of | — | — | — | One axis | — | — | — | — |
| | | stretching | | | | | | | | |
| | | axes | | | | | | | | |

| | | | | | | | | |
|---|---|---|---|---|---|---|---|---|
| Porosity (overall) [%] | 48.3 | 50.0 | 47.6 | 49.2 | 48.6 | 48.8 | 44.3 | 50.9 |
| Thickness (overall) | 200 | 200 | 200 | 200 | 200 | 200 | 200 | 200 |
| [μm] | | | | | | | | |
| Thickness ratio | 0.08 | — | 0.08 | 0.09 | 0.05 | 0.03 | 0.08 | 0.08 |
| (surface layer/substrate | | | | | | | | |
| layer) | | | | | | | | |
| Porosity ratio (surface | 0.82 | — | 0.61 | 0.80 | 0.82 | 0.82 | 0.78 | 0.98 |
| layer/substrate layer) | | | | | | | | |

### Evaluations of Porous Resin Sheets

The porous resin sheets obtained above in Examples and Comparative Examples were evaluated as follows. The results are shown in Tables 4 to 5.

### Rupture Strength

The stress at which the sheet was ruptured in its width direction was measured in accordance with JIS-K7127: 1999 (Plastics-Determination of tensile properties).
Size of test specimen: 15 mm×150 mm
Tensile speed: 300 mm/min

The measurement was performed in triplicate for the same samples to calculate an average.

### Shapability

Each of the porous resin sheets obtained in Examples and Comparative Examples was pressed in a direction from the first surface layer toward the substrate layer under press conditions of 1 MPa/10 sec./ordinary temperature, with the use of a debossing metal plate manufactured by Tsukatani Hamono Mfg. Co., Ltd. (tip: 400 μm×200 μm rectangle, edge angle) 90° and a press machine (Mini Test Press manufactured by Toyo Seiki Seisaku-sho, Ltd.) to form a simulated pocket having a length of 400 μm, a width of 200 μm, and a depth of 90% of the thickness of the sheet. The porous resin sheet was cut across the simulated pocket with a razor blade to observe the cross-sectional shape of the simulated pocket with a digital microscope (HRX-01 manufactured by Hirox Co., Ltd.), and the following evaluations were made.

### Depth

The evaluation was made according to the following criteria.
A: Excellent

A depth of 30 μm or more was achieved, and it was possible to form a simulated pocket having a depth more than 85% and 90% or less of the thickness of the sheet.
B: Good

A depth of 30 μm or more was achieved, and it was possible to form a simulated pocket having a depth more than 80% and 85% or less of the thickness of the sheet.
C: Acceptable

A depth of 30 μm or more was achieved, and it was possible to form a simulated pocket having a depth more than 75% and 80% or less of the thickness of the sheet.
D: Poor

A depth of 30 μm or more was achieved, but it was not possible to form a simulated pocket having a depth more than 75% of the thickness of the sheet.
E: Extremely poor

A depth of 30 μm or more was not achieved.

### Prevention of Tapering

The evaluation was made according to the following criteria.
A: Excellent

The angle between the bottom surface and the side surface was 85° or more.
B: Good

The angle between the bottom surface and the side surface was 80° or more and less than 85°.
C: Acceptable

The angle between the bottom surface and the side surface was 75° or more and less than 80°.
D: Poor

The angle between the bottom surface and the side surface was 60° or more and less than 75°
E: Extremely poor

The angle between the bottom surface and the side surface was less than 60°.

### Bottom Stability

The distance between the bottom of the pocket formed by shaping and the surface of the porous resin sheet opposite from the first surface layer was measured on the cross-sectional image. The measurement was performed on 10 pockets to record the maximum and minimum distances for each of the pockets, and the average of the differences between them was calculated. The bottom stability was evaluated according to the following criteria on the basis of the average.
A: Excellent (The average was 1 μm or less.)
B: Good (The average was more than 1 μm and 3 μm or less.)
C: Acceptable (The average was more than 3 μm and 5 μm or less.)
D: Poor (The average was more than 5 μm and 10 μm or less.)
E: Extremely poor (The average was more than 10 μm.)

TABLE 4

| | | | Example | Example | Comparative | Example | Comparative | Example |
|---|---|---|---|---|---|---|---|---|
| | | | 1 | 2 | Example 1 | 3 | Example 2 | 4 |
| Evaluation | Rupture strength | | 4.3 | 5.0 | 5.6 | 5.2 | 14.4 | 12.3 |
| results | [kgf/mm²] | | | | | | | |
| | Shapability | Depth | A | A | E | A | C | C |
| | | Prevention | A | A | C | C | D | C |
| | | of tapering | | | | | | |
| | | Bottom | B | B | C | B | E | B |
| | | stability | | | | | | |

TABLE 5

| | | | Example | Comparative | Comparative | Example | Example | Example | Example | Example |
|---|---|---|---|---|---|---|---|---|---|---|
| | | | 5 | Example 3 | Example 4 | 6 | 7 | 8 | 9 | 10 |
| Evaluation | Rupture strength | | 4.3 | 3.3 | 4.7 | 3.8 | 4.2 | 4.0 | 6.8 | 3.8 |
| results | [kgf/mm²] | | | | | | | | | |
| | Shapability | Depth | B | A | C | A | A | A | B | A |
| | | Prevention of | C | D | E | A | A | A | C | A |
| | | tapering | | | | | | | | |
| | | Bottom | C | B | D | A | B | C | C | A |
| | | stability | | | | | | | | |

Examples 1 to 10 confirmed that the porous resin sheets according to the present invention had excellent rupture strength and shapability even when the thickness balance, the porosity, the mode of stretching, and the layer structure were changed within their respective predetermined ranges. Further, Examples 1, 7, and 8 confirmed that bottom stability was improved as the thickness of the first surface layer was increased. Further, Examples 9 and confirmed that the porosity of the first surface layer was increased by increasing the particle content in the first surface layer and/or lowering the stretching temperature of the first surface layer, thereby improving shapability.

On the other hand, in the case of the porous resin sheet of Comparative Example 1, the overall thickness of the sheet was insufficient, and therefore a sufficient depth was not achieved by shaping. In the case of the porous resin sheet of Comparative Example 2, the sheet had a low porosity as a whole, and therefore, shapability was poor in terms of prevention of tapering and bottom stability. The porous resin sheet of Comparative Example 3 consisted only of the substrate layer, and therefore shapability was poor in terms of prevention of tapering. In the case of the porous resin sheet of Comparative Example 4, the particle content in the first surface layer was insufficient, and therefore shapability was poor in terms of prevention of tapering and bottom stability.

Although various embodiments of the present invention have been described above with reference to the drawings, it is needless to say that the present invention is not limited to these examples. It is apparent to those skilled in the art that various changes and modifications are possible within the scope of the claims, and that it is, of course, understood that these also belong to the technical scope of the present invention. Further, the components and features of the above embodiments may freely be combined together without departing from the spirit of the present invention.

It should be noted that the present application claims priority to Japanese Patent Application (No. 2022-102194) filed on Jun. 24, 2022, the entire contents of which are incorporated herein by reference.

### Industrial Applicability

The porous resin sheet according to the present invention can suitably be used as a porous resin sheet for carrier tapes.

### Reference Signs List

1 Substrate layer
2 First surface layer
3 Second surface layer
4 Pocket
10 Porous resin layer

1. A porous resin sheet comprising a porous resin layer containing a thermoplastic resin, wherein
the porous resin layer has a thickness of 40 to 350 μm,
the porous resin layer has a porosity of 35 to 80%,
the porous resin layer includes a substrate layer and a first surface layer, and wherein
each of the substrate layer and the first surface layer contains a thermoplastic resin and particles,
a content of the particles in the substrate layer is 20 to 45 mass %, and
a content of the particles in the first surface layer is 45 to 80 mass %.

2. The porous resin sheet according to claim 1, wherein
the first surface layer is a porous uniaxially-stretched resin layer, and
the substrate layer is a porous biaxially-stretched resin layer.

3. The porous resin sheet according to claim 1, wherein the first surface layer has a thickness of 5 μm or more.

4. The porous resin sheet according to claim 1, wherein the first surface layer has a thickness of 10 μm or more.

5. The porous resin sheet according to claim 1, wherein the porous resin layer further includes a second surface layer on a surface of the substrate layer opposite from the first surface layer.

6. The porous resin sheet according to claim 1, wherein a ratio of a porosity of the first surface layer to a porosity of the substrate layer is 0.80 to 1.20.

7. The porous resin sheet according to claim 1, having a rupture strength of 0.1 to 10 kgf/mm² in its width direction.

8. The porous resin sheet according to claim 1, for use in carrier tapes.

9. A carrier tape comprising:
the porous resin sheet according to claim 1, and
a pocket formed in the porous resin sheet. P72491

10. The porous resin sheet according to claim 2, wherein the first surface layer has a thickness of 5 μm or more.

11. The porous resin sheet according to claim 2, wherein the first surface layer has a thickness of 10 μm or more.

12. The porous resin sheet according to claim 2, wherein the porous resin layer further includes a second surface layer on a surface of the substrate layer opposite from the first surface layer.

13. The porous resin sheet according to claim 2, wherein a ratio of a porosity of the first surface layer to a porosity of the substrate layer is 0.80 to 1.20.

14. The porous resin sheet according to claim 2, having a rupture strength of 0.1 to 10 kgf/mm² in its width direction.

15. The porous resin sheet according to claim 2, for use in carrier tapes.

16. A carrier tape comprising:
the porous resin sheet according to claim 2, and
a pocket formed in the porous resin sheet.
